(19) United States
(12) Patent Application Publication
(10) Pub. No.: US 2015/0243494 A1
(43) Pub. Date: Aug. 27, 2015

(54) MECHANICALLY ROBUST SILICON SUBSTRATE HAVING GROUP IIIA-N EPITAXIAL LAYER THEREON

(71) Applicant: Texas Instruments Incorporated, Dallas, TX (US)

(72) Inventors: MICHAEL LOUIS HAYDEN, PLANO, TX (US); THOMAS ANTHONY MCKENNA, WYLIE, TX (US); RICK L. WISE, FAIRVIEW, TX (US); SAMEER PENDHARKAR, ALLEN, TX (US)

(73) Assignee: Texas Instruments Incorporated, Dallas, TX (US)

(21) Appl. No.: 14/189,688

(22) Filed: Feb. 25, 2014

(51) Int. Cl. H01L 21/02; H01L 29/205; H01L 29/778; C30B 29/40; C30B 23/02; C30B 25/18; C30B 23/06; H01L 29/20; C30B 15/04

(52) U.S. Cl. CPC H01L 21/0254; H01L 29/2003; H01L 29/205; H01L 29/7786; H01L 21/02381; H01L 21/02458; C30B 15/04; C30B 23/025; C30B 25/183; C30B 23/066; C30B 29/406; C30B 29/403

(57) ABSTRACT

A method of forming an epitaxial article includes growing a crystal of elemental silicon having a minimum boron doping level of 3.2×10¹⁸/cm³ using Czochralski process parameters including a crystal growth velocity (pull speed) [V] which is less than (<) an average axial temperature gradient [G]. The crystal is cut into at least one elemental silicon substrate having a surface aligned to a <111> direction; wherein a ratio of vacancies/interstitials in the silicon substrate is less than (<) 1. At least one epitaxial buffer layer is grown on the surface of the silicon substrate, and at least one epitaxial Group IIIA-N layer is grown on the buffer layer(s).

### FIELD

Disclosed embodiments relate to epitaxial articles having a Group IIIA-N layer (e.g., GaN) on at least one buffer layer, on a silicon substrate.

### BACKGROUND

Gallium-nitride (GaN) is one commonly used Group IIIA-N material, where Group IIIA elements such as Ga (as well as boron, aluminum, indium, and thallium) are also sometimes referred to as Group 13 elements. GaN is a binary IIIA/V direct bandgap semiconductor that has a Wurtzite crystal structure. Its relatively wide band gap of 3.4 eV at room temperature (vs. 1.1 eV for silicon) affords it special properties for a wide variety of applications in optoelectronics, as well as high-power and high-frequency electronic devices.

Although GaN substrate wafers are commercially available, they are generally expensive. Most integrated circuits are generally fabricated instead on silicon substrates. Primarily as a result of the high volumes of silicon substrates produced for the semiconductor industry, silicon substrates are relatively inexpensive as compared to GaN substrates. It is therefore desirable from a cost point of view to be able to fabricate GaN-based circuits and optoelectronic devices (e.g., LEDs) on relatively inexpensive silicon substrates (e.g., wafers).

However, there are problems with growing high quality GaN epitaxial layers on silicon substrates. Many of the problems associated with growing high quality GaN epitaxial layers on silicon substrates are because the lattice constant of silicon is substantially different from the lattice constant of GaN, with the lattice mismatch between GaN and silicon being about of 16.9%. When GaN is grown epitaxially on a silicon substrate, the epitaxial material being grown may exhibit an undesirably high density of lattice defects. If the GaN layer is grown to be thick enough for most applications, then stress within the GaN layer may also result in a cracking in the latter-grown portions of the GaN material, particular towards the outer edge of the substrate.

Moreover, silicon and GaN have different coefficients of thermal expansion (CTE), with the CTE being about 5.6×10⁻⁶/K for GaN and about 3.4×10⁻⁶/K for silicon. If the temperature of a structure involving GaN on a silicon substrate is increased, for example, then the silicon material portion of the structure will expand at a different (lower) rate as compared to the rate at which the GaN material expands. These different CTE's give rise to stress between the various layers of the device. This stress may cause cracking and other problems. For example, relatively thick (e.g., >1 μm) GaN epilayers are known to have a tendency to crack upon cooling to room temperature due to the severe tensile stress induced by the 35 to 40% smaller CTE of Si.

Furthermore, it is difficult to grow GaN on a silicon substrate because GaN is a compound material and Si is an elemental material. The transition from nonpolar to polar structure, combined with the substantial lattice mismatch, generates crystal defects during growth of the GaN layer. One solution is tailoring one or more “buffer” layers between the Si and GaN layers to help overcome lattice constant mismatch and crystal structure differences between GaN and Si for GaN epitaxial layer(s) on silicon devices.

### SUMMARY

This Summary is provided to introduce a brief selection of disclosed concepts in a simplified form that are further described below in the Detailed Description including the drawings provided. This Summary is not intended to limit the claimed subject matter's scope.

As described above, conventional solutions to overcome the lattice constant and crystal structure differences between Group IIIA-N materials (e.g., GaN) and Si involve modifying the buffer layer(s) between the Group IIIA-N material and Si. Disclosed approaches instead include altering the Si substrate's mechanical properties to provide a high Young's modulus relative to conventional silicon substrates to be more resilient to deformation during the epitaxial depositions of buffer layers(s) and Group IIIA-N layers, and subsequent thermal device processing.

Disclosed embodiments recognize the combination of an elemental silicon <111> substrate (e.g., wafer) being p⁺⁺ doped provides a high Young's modulus (e.g., at least 20% higher) relative intrinsic silicon, n-doped silicon, or moderately to lightly p-doped silicon, as well as the substrate being interstitial silicon rich as compared to the concentration of lattice vacancies, together retards precipitation of interstitial oxygen in the substrate as well as bulk micro defect (BMD) formation. Retarding precipitation of interstitial oxygen and BMD formation reduces overall substrate deformation in subsequent thermal processing steps, such as high temperature steps including source/drain activation to form high voltage power electronic or high temperature processing for optoelectronic devices, from the stress differential due to the Group IIIA-N layer (e.g., GaN) on buffer layer(s) on the silicon substrate described in the Background above which can lead to cracking. As used herein, p⁺⁺ doping refers to a minimum boron doping density of 3.2×10¹⁸/cm³, such as 3.2×10¹⁸/cm³ to 1.2×10²⁰/cm³ which corresponds to a room temperature bulk resistivity of about 1 mohm-cm to about 20 mohm-cm.

### BRIEF DESCRIPTION OF THE DRAWINGS

Reference will now be made to the accompanying drawings, which are not necessarily drawn to scale, wherein:

FIG. 1 is a flow chart that shows steps in an example method for forming an epitaxial article including a Group IIIA-N layer on at least one buffer layer on a p⁺⁺ doped elemental silicon <111> substrate (e.g., wafer), according to an example embodiment.

FIG. 2A is a cross-sectional diagrams showing a disclosed epitaxial article having a single buffer layer, according to an example embodiment.

FIG. 2B is a cross-sectional diagram showing a disclosed epitaxial article having a first buffer layer and a second buffer layer, according to an example embodiment.

FIG. 3A is a cross sectional view of an example depletion-mode high electron mobility transistor (HEMT) power device with the Group IIIA-N layer shown in FIG. 2B on the buffer layers being a bi-layer stack comprising a first Group IIIA-N layer on a second different Group IIIA-N layer, according to an example embodiment.

FIG. 3B is a cross sectional view of an example enhancement-mode HEMT power device with a normally off gate with the Group IIIA-N layer shown in FIG. 2B on the buffer layers being a bi-layer stack comprising a first Group IIIA-N layer on a second different Group IIIA-N layer, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

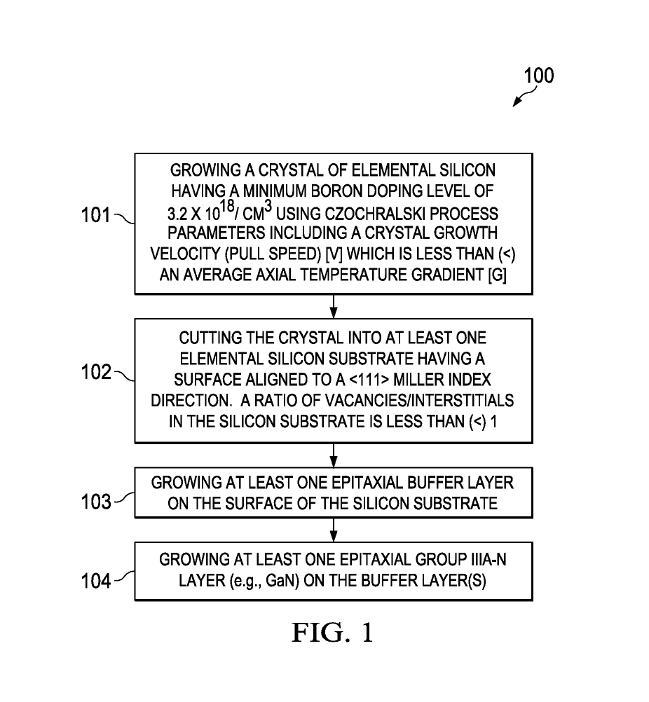

FIG. 1 is a flow chart that shows steps in an example method 100 for forming an epitaxial article including a Group IIIA-N layer on at least one buffer layer on a p⁺⁺ doped elemental silicon <111> substrate (e.g., wafer), according to an example embodiment. Elemental silicon can be contrasted with compound silicon, such as silicon carbide (SiC) used for SiC substrates.

Step 101 comprises growing a crystal of elemental silicon having a minimum boron doping level of 3.2×10¹⁸/cm³ using Czochralski process parameters including a crystal growth velocity (pull speed) [V] which is less than (<) an average axial temperature gradient [G]. When silicon is grown by the Czochralski method, as known in the art, the melt is contained in a silica (quartz) crucible so that during silicon crystal growth, the walls of the crucible dissolve into the melt and Czochralski grown silicon therefore contains oxygen at a typical concentration of about 10¹⁸ cm⁻³. The Young's modulus of disclosed silicon substrates is generally >20% higher as compared to a Young's modulus of intrinsic silicon, and can be 30% or more higher for higher disclosed boron doping levels.

As noted above, the boron doping level is generally between 3.2×10¹⁸/cm³ and 1.2×10²⁰/cm³. Disclosed embodiments recognize compared with undoped and lightly doped silicon, heavily boron-doped silicon has about a 0.8% higher thermal expansion coefficient and a 20% to 30% higher Young's modulus. Young's modulus, also known as the tensile modulus or elastic modulus, is a measure of the stiffness of an elastic isotropic material and is a quantity used to characterize materials, being defined as the ratio of the stress along an axis over the strain along that axis in the range of stress in which Hooke's law holds.

Step 102 comprises cutting the crystal into at least one elemental silicon substrate (and generally a large number, such as hundreds of elemental silicon substrates) having a surface aligned to a <111> Miller index direction. A ratio of vacancies/interstitials in the silicon substrate is less than (<) 1, typically being <½, thus being interstitial rich silicon.

U.S. Pat. No. 6,254,672 to Falster et al. (hereafter Falster) discloses specifics with regard to the [V]/[G] ratio obtained during silicon crystal growth, which can be used to create low defect interstitially rich silicon during silicon crystal growth where [V] is the crystal growth velocity (pull speed) and [G] is the average axial temperature gradient. Falster is incorporated by reference into this application. It is the manipulation of the [V]/[G] ratio that moves the vacancy/interstitial boundary within the silicon crystal in a radial direction. High V/G growth conditions are recognized to result in vacancy dominated silicon, while low V/G growth conditions will result in interstitial dominated silicon, which is utilized for disclosed embodiments.

A mechanism is described below that is believed to explain the observed mechanical robustness provided by disclosed epitaxial articles. Although the mechanism described below is believed to be accurate, disclosed embodiments may be practiced independent of the particular mechanism(s) that may be operable. Individual oxygen atoms dispersed in interstitial Czochralski silicon crystal sites at a given concentration have almost no influence on the mechanical strengths of originally essentially dislocation-free crystals at elevated temperature. Silicon crystals grown under disclosed low V/G conditions become rich in silicon self interstitials instead of silicon vacancies. These interstitial point defects (silicon self interstitials) at elevated concentrations form punch out dislocation loops within the silicon crystal. Oxygen atoms in a dislocated crystal congregate on dislocations at rest and lock the latter effectively. As a result, a dislocated crystal involving a high concentration of oxygen atoms behaves like a crystal with a much lower density of dislocations than the actual one and shows a high mechanical strength. The activation fraction of dislocations existing before deformation decreases as the concentration of oxygen atoms in the crystal increases. As a result, the underlying p⁺⁺ substrate rich in silicon self interstitials will experience less bow and warp deformation than a p⁺⁺ substrate rich in vacancy point defects that permits interstitial oxygen to precipitate out of solution.

For disclosed embodiments, before cutting into a plurality of substrates (e.g., wafers), the silicon crystal surface is aligned in the <111> relative direction known as a <111> crystal orientation. The <111> crystal orientation is used for disclosed embodiments due to its recognized superior mechanical properties over other crystal orientations.

As disclosed above, the ratio of vacancies/interstitials in the silicon substrate can be less than (<) 0.5. Moreover, as disclosed above, a low ratio of vacancies/interstitials in the silicon substrate can be obtained by low V/G growth conditions which results in interstitial dominated silicon.

Step 103 comprises growing at least one epitaxial buffer layer on the surface of the silicon substrate. The epitaxial buffer layer can include at least a first Group IIIA-N layer and a second Group IIIA-N layer different from the first Group IIIA-N layer on the first Group IIIA-N layer. The first Group IIIA-N buffer layer and second Group IIIA-N buffer layer can be selected from BN, AlN, GaN, AlGaN and InN, or their ternary and quaternary mixtures. The buffer layer(s) can have varying thicknesses of about hundreds to about thousands of angstroms to several microns, and can be formed by various known epitaxial growth techniques. The buffer layer(s) can function as a stress relief layer. The forming of the buffer layer(s) can comprise molecular-beam epitaxy (MBE), metal organic chemical vapor deposition (MOCVD), or halide vapor phase epitaxy (HVPE).

Step 104 comprises growing at least one epitaxial Group IIIA-N layer (e.g., GaN) on the buffer layer(s). The Group IIIA nitride compound semiconductors may be represented by the general formula AlₓGa_{y}In_{1-x-y}N, where 0≦x≦1, 0≦y≦1, 0≦x+y≦1. For example, the Group IIIA-N layer can comprise at least one of GaN, InN, AlN, AlGaN, AlInN, InGaN, and AlInGaN. Other Group IIIA elements such as boron (B) may be included, and N may be partially replaced by phosphorus (P), arsenic (As), or antimony (Sb). Each of the Group IIIA nitride compound semiconductors may contain an optional dopant selected from Si, C, Ge, Se, O, Fe, Mn, Mg, Ca, Be, Cd, and Zn. The forming of the Group IIIA nitride compound semiconductor layer(s) may also be formed by MBE, MOCVD or HVPE.

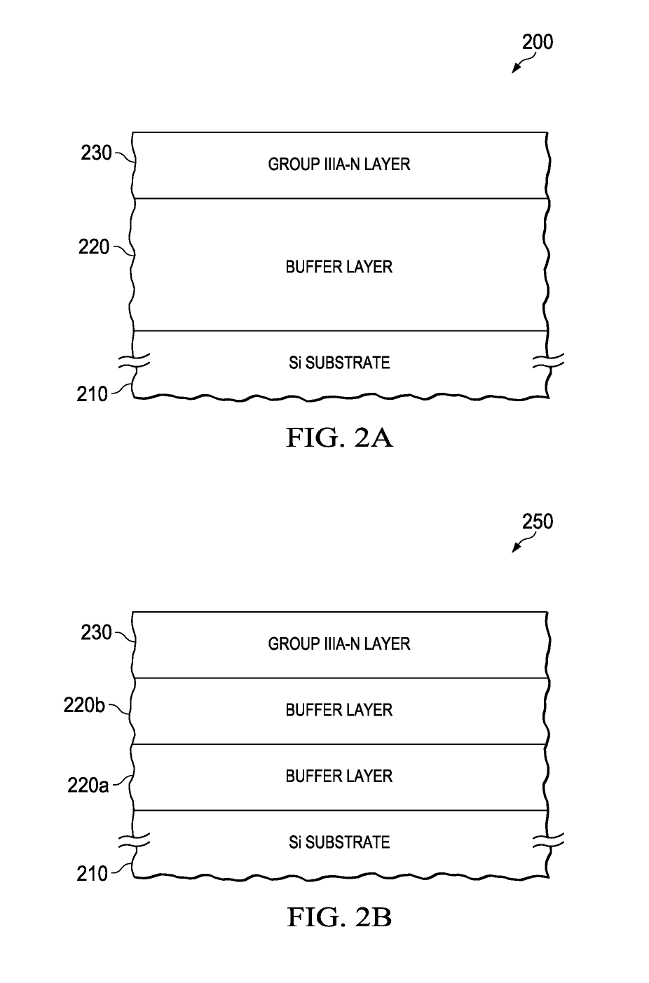

FIG. 2A is a cross-sectional diagrams showing a disclosed epitaxial article 200 having a single buffer layer, according to an example embodiment. Epitaxial article 200 includes a Group IIIA-N layer 230, on a buffer layer 220, on an elemental silicon substrate 210 having a minimum boron doping level of 3.2×10¹⁸/cm³, a surface aligned to a <111> Miller index direction, and a ratio of vacancies/interstitials in the silicon substrate <1, thus being interstitial rich silicon.

FIG. 2B is a cross-sectional diagrams showing a disclosed epitaxial article 250 having a first buffer layer 220a on elemental silicon substrate 210 and a second buffer layer 220b on the first buffer layer 220a, according to an example embodiment. Although only 2 buffer layers are shown, the number of buffer layers can be three or more. A Group IIIA-N layer 230 is on the second buffer layer 220b.

One example of a power semiconductor device is a HEMT. A HEMT, also known as heterostructure FET (HFET) or modulation-doped FET (MODFET), is a field-effect transistor incorporating a junction between two semiconductor materials with different band gaps (i.e. a heterojunction) as the channel instead of a doped region (as is generally the case for a Metal-oxide-semiconductor field-effect transistor (MOSFET)). The HEMT includes a 2DEG used as a carrier in a channel layer. Since the 2DEG is used as a carrier, the electron mobility of the HEMT is higher than that of other general transistors. The HEMT includes a compound semiconductor having a wide band gap. Therefore, a breakdown voltage of the HEMT may be greater than that of other general transistors. The breakdown voltage of the HEMT may increase in proportion to a thickness of the compound semiconductor layer including the 2DEG, for example, a GaN layer.

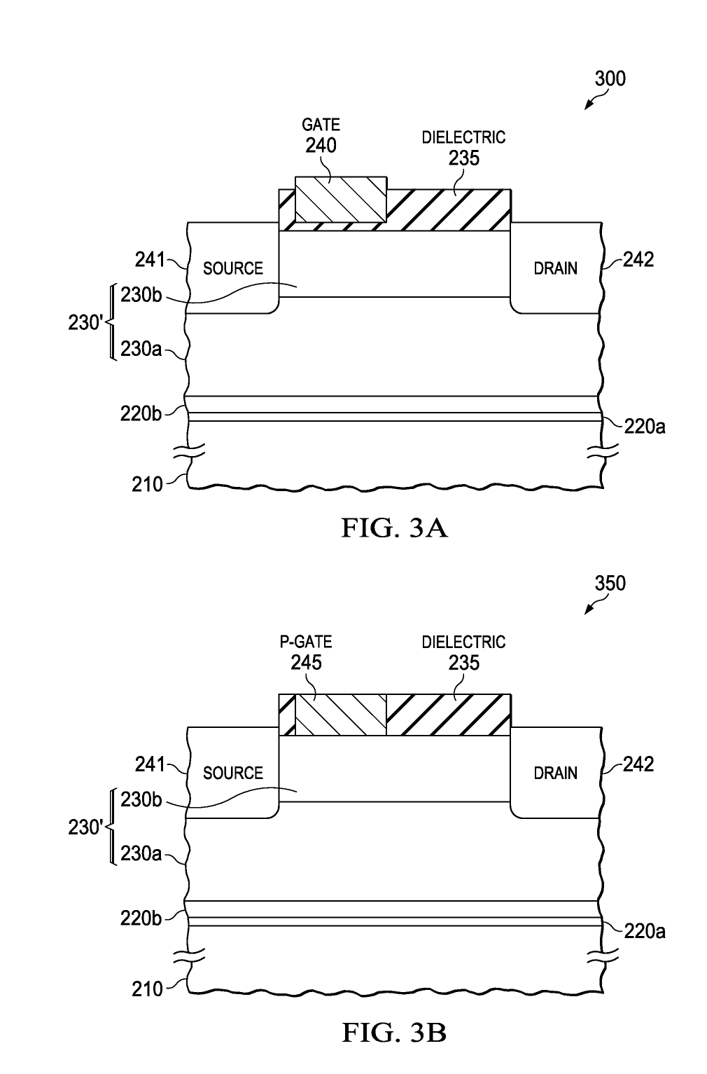

FIG. 3A is a cross sectional view of an example depletion-mode HEMT power device 300 with the Group IIIA-N layer 230 shown in FIG. 2B now shown as 230′ being a bi-layer stack comprising a first Group IIIA-N layer 230b on a second different Group IIIA-N layer 230a, according to an example embodiment. The first Group IIIA-N layer 230b is shown on a portion of the second Group IIIA-N layer 230a. Although the Group IIIA-N layer 230′ is shown as a bi-layer', the Group IIIA-N layer 230′ can be only a single layer, or three or more different Group IIIA-N layers. Generally, the Group IIIA-N layer 230′ may include one or more of GaN, InN, AlN, AlGaN, AlInN, InGaN, and AlInGaN. As noted above the Group IIIA-N layers can include other Group IIIA elements such as B, and N may be partially replaced by P, As, or Sb, and may also contain an optional dopant. In one specific example, the Group IIIA-N layer 230′ comprises a GaN layer on top of an AlₓGa_{y}N layer or an InₓAl_{y}N layer.

The 2DEG of HEMT power device 300 is at the Group IIIA-N layer interface 230b/230a. As noted above, in another embodiment the Group IIIA-N layer 230′ can be more than two Group IIIA-N layers (e.g., 3-4 layers), such as each being an AlₓGa_{y}N layer or InₓAl_{y}N layer having a different value of x% and y%, where 0≦x, y≦1 and x+y=1. A specific example is the Group IIIA-N layer 230′ being a tri-layer stack comprising GaN on InAlN on AlGaN.

HEMT power device 300 includes a source 241, a drain 242, and a gate electrode 240. Gate electrode 240 is positioned between the source 241 and drain 242, closer to the source 241 than the drain 242. Although the gate electrode 240 is shown having an underlying gate dielectric 235 which physically and electrically separates the gate electrode 240 from the first Group IIIA-N layer 230b, the first Group IIIA-N layer 230b can instead be in direct contact with the underlying second IIIA-N layer 230a. The source 241, drain 242, and gate electrode 240 may be formed of metals and/or metal nitrides, but example embodiments are not limited thereto.

FIG. 3B is a cross sectional view of an example enhancement-mode HEMT power device 350 with a normally off gate with the Group IIIA-N layer 230 shown in FIG. 2B as 230′ being a bi-layer stack comprising a first Group IIIA-N layer 230b on a second different Group IIIA-N layer 230a, according to an example embodiment. In this embodiment, the gate electrode 245 is a p-doped gate electrode that is in direct contact with the first Group IIIA-N layer 230b.

Advantages of disclosed embodiments include altering the nature of the intrinsic point defects in silicon substrates from vacancy rich to silicon interstitial rich during the silicon crystal growth process. The use of interstitial rich silicon retards the precipitation of interstitial oxygen in the substrate due to the lack of silicon vacancies which provide a template for precipitation. The mechanical strength of the silicon substrate is maintained due to the oxygen remaining in solution rather than precipitating into the formation of bulk micro defects (BMDs) during subsequent wafer fab processing, leading to a significant reduction in cracking, and thus higher yields. Moreover, disclosed embodiments can be implemented during the crystal growth process for the p⁺⁺ substrate using industry standard equipment and processes and does not require any change to the buffer layer(s) and GaN epitaxial layer(s), along with potentially any wafer fab processing.

Disclosed embodiments can be used to form semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, Insulated Gate Bipolar Transistor (IGBT), CMOS, BiCMOS and MEMS. Disclosed embodiments can also used to form for a wide variety of optoelectronic devices, including light-emitting diodes (LEDs) and lasers including laser diodes.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A method of forming an epitaxial article, comprising:
growing a crystal of elemental silicon having a minimum boron doping level of 3.2×10¹⁸/cm³ using Czochralski process parameters including a crystal growth velocity (pull speed) [V] which is less than (<) an average axial temperature gradient [G];
cutting said crystal into at least one elemental silicon substrate having a surface aligned to a <111> direction; wherein a ratio of vacancies/interstitials in said elemental silicon substrate is less than (<) 1;
growing at least one epitaxial buffer layer on said surface of said elemental silicon substrate, and
growing at least one epitaxial Group IIIA-N layer on said buffer layer.

2. The method of claim 1, wherein a Young's modulus of said elemental silicon substrate is ≧25% higher as compared to a Young's modulus of intrinsic silicon.

3. The method of claim 1, wherein said boron doping level is between 8.4×10¹⁸/cm³ and 1.2×10²⁰/cm³.

4. The method of claim 1, wherein said ratio of vacancies/interstitials is less than (<) 0.5.

5. The method of claim 1, wherein said Group IIIA-N layer on said buffer layer includes at least a first Group IIIA-N layer and a second Group IIIA-N layer different from said first Group IIIA-N layer, said first Group IIIA-N layer being on said second Group IIIA-N layer, and wherein said second Group IIIA-N layer and said first Group IIIA-N layer both comprise AlₓGa_{y}N or InₓAl_{y}N where 0≦x, y≦1 and x+y=1.

6. The method of claim 5, wherein said second Group IIIA-N layer comprises GaN and said first Group IIIA-N layer comprises AlGaN.

7. The method of claim 1, wherein said growing said Group IIIA-N layer comprises molecular-beam epitaxy (MBE), metal-organic chemical vapor deposition (MOCVD) or halide vapor phase epitaxy (HVPE).

8. The method of claim 1, wherein said buffer layer comprises BN, AlN, GaN, AlGaN or InN, or their ternary or quaternary mixtures.

9. An epitaxial article, comprising:
an elemental silicon substrate having a minimum boron doping level of 3.2×10¹⁸/cm³ and a surface aligned to a <111> direction; wherein a ratio of vacancies/interstitials in said elemental silicon substrate is less than (<) 1;
at least one epitaxial buffer layer on a surface of said elemental silicon substrate, and
at least one epitaxial Group IIIA-N layer on said buffer layer.

10. The epitaxial article of claim 9, wherein said boron doping level is between 8.4×10¹⁸/cm³ and 1.2×10²⁰/cm³.

11. The epitaxial article of claim 9, wherein a Young's modulus of said elemental silicon substrate is ≧25% higher as compared to a Young's modulus of intrinsic silicon.

12. The epitaxial article of claim 9, wherein said ratio of vacancies/interstitials is less than (<) 0.5.

13. The epitaxial article of claim 9, wherein said at least one epitaxial Group IIIA-N layer on said buffer layer includes at least a first Group IIIA-N layer and a second Group IIIA-N layer different from said first Group IIIA-N layer, said first Group IIIA-N layer being on said second Group IIIA-N layer, and wherein said second Group IIIA-N layer and said first Group IIIA-N layer both comprise AlₓGa_{y}N or InₓAl_{y}N where 0≦x, y≦1 and x+y=1.

14. The epitaxial article of claim 13, wherein said second Group IIIA-N layer comprises GaN and said first Group IIIA-N layer comprises AlGaN.

15. The epitaxial article of claim 14, further comprising a layer of InAlN between said second Group IIIA-N layer and said first Group IIIA-N layer.

16. A semiconductor power device, comprising:
an elemental silicon substrate having a minimum boron doping level of 3.2×10¹⁸/cm³ and a surface aligned to a <111> direction; wherein a ratio of vacancies/interstitials in said elemental silicon substrate is less than (<) 1;
at least one epitaxial buffer layer on a surface of said elemental silicon substrate, and
at least a first epitaxial Group IIIA-N layer on said buffer layer;
a source, a drain, and a gate electrode on said first epitaxial Group IIIA-N layer.

17. The semiconductor power device of claim 16, wherein said ratio of vacancies/interstitials is less than (<) 0.5.

18. The semiconductor power device of claim 16, wherein said epitaxial Group IIIA-N layer on said buffer layer includes at least a first Group IIIA-N layer and a second Group IIIA-N layer different from said first Group IIIA-N layer, said first Group IIIA-N layer being on said second Group IIIA-N layer, and wherein said second Group IIIA-N layer and said first Group IIIA-N layer both comprise AlₓGa_{y}N or InₓAl_{y}N wherein 0≦x, y≦1 and x+y=1.

19. The semiconductor power device of claim 18, wherein said second Group IIIA-N layer comprises GaN and said first Group IIIA-N layer comprises AlGaN.

20. The semiconductor power device of claim 16, wherein said boron doping level is between 8.4×10¹⁸/cm³ and 1.2×10²⁰/cm³.

21. A method of forming an epitaxial article, comprising:
growing at least one epitaxial buffer layer on a surface of an elemental Czochralski silicon substrate having a surface aligned to a <111> direction; wherein a ratio of vacancies/interstitials in said elemental silicon substrate is less than (<) 1; and wherein a minimum boron doping level is 3.2×10¹⁸/cm³, and
growing at least one epitaxial Group IIIA-N layer on said buffer layer.
